(19) United States
(12) Patent Application Publication
(10) Pub. No.: US 2007/0069387 A1
(43) Pub. Date: Mar. 29, 2007

(54) Semiconductor device and method of forming the same

(76) Inventor: Kim Dae Kyeun, Yongin-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/528,076

(22) Filed: Sep. 26, 2006

(30) Foreign Application Priority Data
Sep. 28, 2005 (KR) 10-2005-0090681

(51) Int. Cl. H01L 23/48

(52) U.S. Cl. 257/760

(57) ABSTRACT

Provided is a method of forming a contact hole. The method includes: depositing an interlayer insulating layer on a semiconductor substrate on which a dummy region and an active region are defined; coating a photoresist film on the interlayer insulating layer; patterning the photoresist film using a mask having a light transmission region, a partial light transmission region and a light shielding region; and etching the patterned photoresist film and the interlayer insulating layer to form a contact hole at the active region and a dummy contact hole at the dummy region.

### RELATED APPLICATION

This application claims the benefit under 35 U.S.C. §119(e) of Korean Patent Application Number 10-2005-0090681 filed Sep. 28, 2005, which is incorporated herein by reference in its entirety.

### FIELD OF THE INVENTION

The present invention relates to a semiconductor device, and more particularly, to a semiconductor device with a design suitable for forming a contact hole used as a contact support (CS) or via hole to enhance the device reliability and performance, and a method of forming the same.

### BACKGROUND OF THE INVENTION

In order to minimize the influence of a fabrication process on pattern dependency, dummy patterns are used in addition to real patterns associated with a device operation. The dummy patterns include patterns formed with respect to an active region, a polysilicon layer, and/or a metal layer using a design rule.

However, in the case of the patterns associated with a contact, such as a contact support ‘CS’, a ‘Via’ and the like, if dummy patterns are inserted according to the related art method, a connection may occur between a lower layer and an upper layer. Therefore, dummy patterns for the ‘CS’ and ‘Via’ are typically not configured.

Where a ‘CS’ or a ‘Via’ is configured without dummy patterns, the fabrication process maintains a serious ID bias (i.e., difference in CD bias between isolation pattern and dense pattern), and such a deficiency in the uniformity remains during the chemical-mechanical polishing process, which is a finishing process for the ‘CS’ or ‘Via’.

Also, in the case of a reactive ion etching (RIE) process for forming a polymer, the polymer below the ‘CS’ or ‘Via’ may be formed differently depending on the pattern density. As a result, while the quality and thickness of layers in which the ‘CS’ and the ‘Via’ are formed are equal to each other, a defect where the ‘CS’ or the ‘Via’ is not completely opened can occur due to a difference in the pattern density, which can have a serious influence on the device reliability and performance.

Hereinafter, a method of forming a contact hole according to the related art will be described with reference to the accompanying drawings.

FIGS. 1A through 1C are sectional views illustrating a method of forming a contact hole according to the related art, FIG. 2 is a photograph showing contact hole sizes in an isolated pattern and a dense pattern for a comparison, and FIG. 3 is a photograph showing an opening failure of a contact hole according to the related art.

First, referring to FIG. 1, an interlayer insulating layer 11 is deposited on a semiconductor substrate 10 having a switching device or an interconnection line (not shown) formed thereon, and then a photoresist film 12 is coated on the interlayer insulating layer 11.

Next, a photomask 13 is aligned over the photoresist film 12. The photomask 13 is configured to include a light transmission region 13a corresponding to CS or Via hole to be formed and a light shielding region 13b corresponding to a region other than the CS or Via hole.

Referring to FIG. 1b, the photoresist film 12 is patterned by a selective exposure and development using the photomask 13 to expose the interlayer insulating layer 11 corresponding to the light transmission region.

Referring to FIG. 1C, the interlayer insulating layer 11 is etched using the patterned photoresist film 12 as an etch mask to form contact holes 14a and 14b for the CS or Via hole.

In the aforementioned related art, a dummy contact hole for the dummy CS or dummy via hole is not formed.

Thus, since the related art semiconductor device does not have a dummy contact hole, the contact holes used for a device operation region may have different sizes in an isolation pattern region compared to a dense pattern region.

Referring to FIGS. 2A and 2B, the size of the contact hole in the isolation region (FIG. 2A) is smaller than the size of the dense region (FIG. 2B). Accordingly, a non-uniformity problem in the size of the contact hole may occur.

To overcome the aforementioned non-uniformity problem, the related art employs an optical proximity correction (OPC) method.

Also, although a lower interlayer insulating layer tends to have little or no difference in the layer quality or thickness, the formation degree of a polymer layer is different, so that an opening failure of a CS in an isolated region or a via hole may occur (refer to region ‘A’ in FIG. 3).

### SUMMARY OF THE INVENTION

Accordingly, the present invention is directed to a semiconductor device and method for manufacturing the same that addresses and/or substantially obviates one or more problems, limitations, and/or disadvantages of the related art.

An object of the present invention is to provide a semiconductor device with a design suitable for forming a contact hole used as a contact support (CS) or via hole to enhance the device reliability and performance, and a method of forming the same.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method of forming a contact hole, including: depositing an interlayer insulating layer on a semiconductor substrate on which a dummy region and an active region are defined; coating a photoresist film on the interlayer insulating layer; patterning the photoresist film using a mask having a light transmission region, a partial light transmission region and a light shielding region; and etching the patterned photoresist film and the interlayer insulating layer to form a contact hole at the active region and a dummy contact hole at the dummy region.

In another aspect of the present invention, there is provided a semiconductor device including: a semiconductor substrate on which a dummy region and an active region are defined; an interlayer insulating layer formed on the semiconductor substrate; a contact hole formed on the active region of the semiconductor substrate; and a dummy contact hole formed on the dummy region of the semiconductor substrate.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A through 1C are sectional views illustrating a method of forming a contact hole according to the related art;

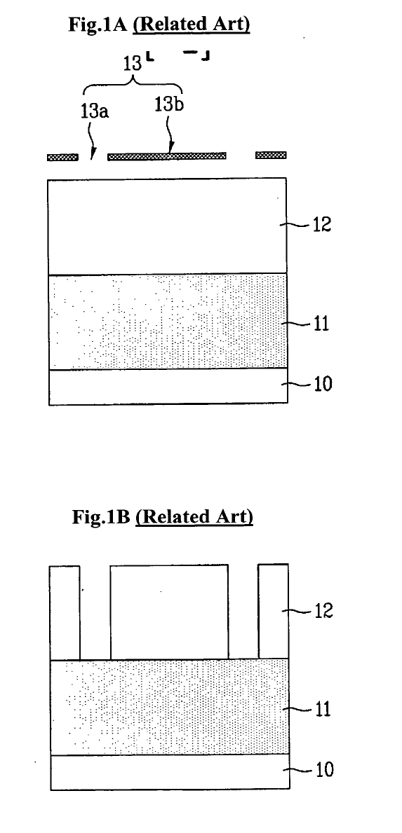

FIG. 2 is a photograph showing contact hole sizes in an isolated pattern and a dense pattern for a comparison;

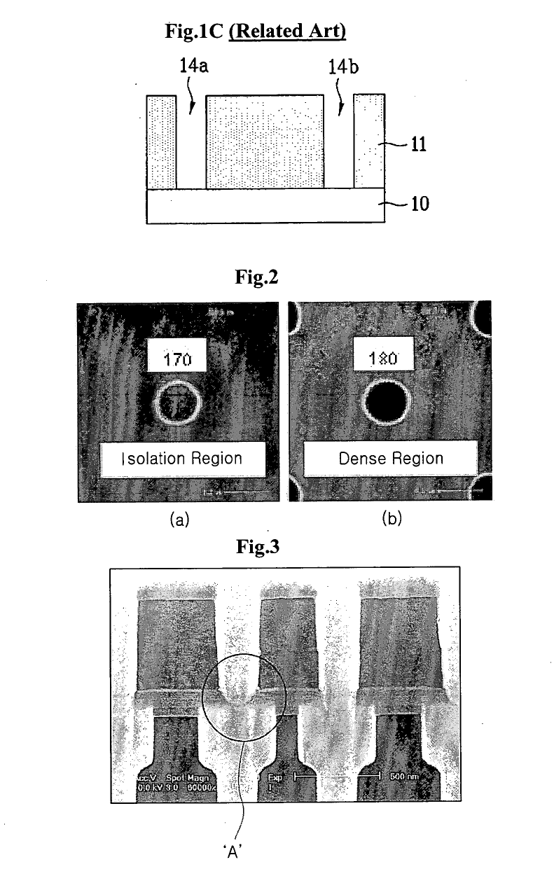

FIG. 3 is a photograph showing an opening failure of a contact hole according to the related art; and

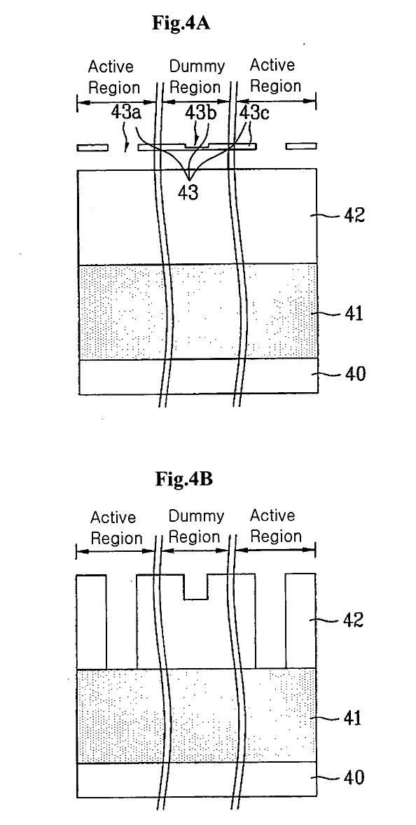

FIGS. 4A through 4C are sectional views illustrating a method of forming a contact hole according to an embodiment of the present invention.

### DETAILED DESCRIPTION OF THE INVENTION

Reference will be made in detail to the preferred embodiments of the present invention, examples of which are illustrated in the accompanying drawings.

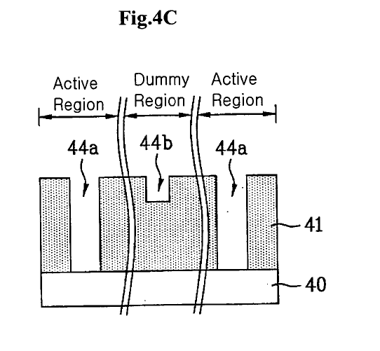

FIGS. 4A through 4C are sectional views illustrating a method of forming a contact hole according to an embodiment of the present invention.

Referring to FIG. 4A, in a method of forming a contact hole for a semiconductor device according to an embodiment of the present invention, an interlayer insulating layer 41 can be deposited on a semiconductor substrate 40 on which a dummy region and an active region are defined and a switching element and an interconnection line (not shown) are formed. A photoresist film 42 can then be coated on the interlayer insulating layer 41.

Thereafter, a photomask 43 can be aligned over the photoresist film 42. The photomask 43 can be configured to include a light transmission region 43a corresponding to a portion for forming a contact hole to be used as a CS or via hole in an active region, a partial light transmission region 43b corresponding to a portion for forming a contact hole to be used as a CS or via hole in a dummy region, and a light shielding region 43c corresponding to a region other than the light transmission regions 43a and 43b.

That is, the photomask 43 having a higher light transmittance in a predetermined portion of the active region than in a predetermined portion of the dummy region can be disposed over the photoresist film 42.

Next, referring to FIG. 4B, the photoresist film 42 can be selectively exposed and developed using the photomask 43 having the light transmission region 43a, the partial light transmission region 43b and the light shielding region 43c.

By doing so, the photoresist film 42 can be patterned such that the interlayer insulating layer 41 is exposed at a portion corresponding to the light transmission region 43a of the active region and partially remains on a portion corresponding to the partial light transmission region of the dummy region.

In other words, the removal depth of the photoresist film can be adjusted by adjusting the light transmittance in the partial light transmission region 43b for forming a dummy contact hole for use as a CS or via hole, or by adjusting thickness of the photoresist film 42. Thus, by adjusting the removal depth in the patterning, it is possible to adjust the depth of a CS or via hole to be formed in the dummy region in a following etching process.

Next, referring to FIG. 4C, the patterned photoresist film 42 and the interlayer insulating layer 41 can be etched to form contact holes 44a to be used as a CS or via hole in the active region.

At this time, in the dummy region where a CS or via hole is formed, the interlayer insulating layer 41 is not opened due to the thickness of the patterned photoresist film 42 but, rather, forms a groove 44b at a predetermined depth.

In the above embodiment, the thickness of the photoresist film 42 can be set to such a degree that a contact hole can be formed in the active region while the photoresist film 42 and the interlayer insulating layer 41 are etched by a predetermined process.

In another embodiment, the photomask 43 may have a plurality of partial light transmission regions in one reticle at a portion corresponding to the dummy region. The plurality of partial light transmission regions can be arranged according to the position of a contact hole and the characteristic of a contact in the dummy region.

Also, an overall area of the contact hole area, including the contact holes and the dummy contact holes can be adjusted at a predetermined percentage with respect to an entire area of the semiconductor substrate 40. For example, 20% to 40% of the entire area of the semiconductor substrate 40 can be used for the contact hole area in order to decrease a failure due to the non-uniformity of contact hole size between the isolation region and the dense region.

After a contact hole is formed as above, it can be filled with a barrier layer and, in a specific embodiment, a tungsten (W) layer. Then, a chemical-mechanical polishing (CMP) process can be performed.

Subsequently, in the case of an aluminum (Al) interconnection line formation process, an Al interconnection line can be completed by a CMP process after the contact hole is filled with a barrier layer and the tungsten layer. In the case of copper (Cu) interconnection line formation process, a CS process can be performed in the same manner as that of the Al interconnection line formation process, but a via hole formation process using copper can be formed differently. In one embodiment, the via hole formation process includes performing a trench process and a via hole opening, forming a barrier layer and a copper layer in the via hole and trench, and then performing a CMP process.

The aforementioned method according to the present invention has advantages in that it can be applied to devices having various line widths ranging from 0.18 μm to 90 μm or more, does not have a special difficulty in realizing the technique, and also does not need an additional investment. In further embodiments, the method can be also applied in forming dummy patterns for polysilicon and metal layer.

As described above, according to the present invention, a contact hole used as a CS or via hole can be formed in an active region and a dummy region using a photomask having different light transmittance, thereby enabling formation of a contact hole with a high reliability and enhanced performance without an opening failure.

It will be apparent to those skilled in the art that various modifications and variations can be made in the present invention. Thus, it is intended that the present invention covers the modifications and variations of this invention provided they come within the scope of the appended claims and their equivalents.

I claim:

1. A method of forming a contact hole, the method comprising:
depositing an interlayer insulating layer on a semiconductor substrate on which a dummy region and an active region are defined;
coating a photoresist film on the interlayer insulating layer;
patterning the photoresist film using a mask having a light transmission region, a partial light transmission region and a light shielding region; and
etching the patterned photoresist film and the interlayer insulating layer to form a contact hole at the active region and a dummy contact hole at the dummy region.

2. The method according to claim 1, wherein the light transmission region of the mask corresponds to the active region of the semiconductor substrate and the partial light transmission region corresponds to the dummy region of the semiconductor substrate.

3. The method according to claim 1, wherein the patterning of the photoresist film is performed such that the photoresist film is completely exposed at a portion corresponding to the light transmission region of the mask and is partially exposed at a portion corresponding to the partial light transmission region of the mask.

4. The method according to claim 1, wherein the contact hole formed at the active region exposes the semiconductor substrate and the dummy contact hole formed at the dummy region is formed without exposing the semiconductor substrate by partially etching the interlayer insulating layer.

5. The method according to claim 4, wherein the dummy contact hole formed at the dummy region has a depth adjusted by adjusting light transmittance of the partial light transmission region of the mask.

6. The method according to claim 4, wherein the dummy contact hole formed at the dummy region has a depth adjusted by adjusting a thickness of the photoresist film coated on the semiconductor substrate.

7. The method according to claim 1, wherein the mask comprises a plurality of partial light transmission regions having several transmittances at a portion corresponding to the dummy region.

8. The method according to claim 1, after etching the patterned photoresist film and the interlayer insulating layer to form the contact hole, further comprising filling the contact hole with a metal and performing a chemical-mechanical polishing process.

9. The method according to claim 8, wherein the metal is at least one selected from the group consisting of tungsten (W), aluminum (Al) and copper (Cu).

10. The method according to claim 1, further comprising adjusting a number of contact holes and dummy contact holes formed in the interlayer insulating layer to decrease a failure occurrence due to a difference in size of the contact holes and dummy contact holes formed on the active region and the dummy region, respectively, of the semiconductor substrate.

11. A semiconductor device comprising:
a semiconductor substrate on which a dummy region and an active region are defined;
an interlayer insulating layer formed on the semiconductor substrate;
a contact hole formed on the active region of the semiconductor substrate; and
a dummy contact hole formed on the dummy region of the semiconductor substrate.

12. The semiconductor device according to claim 11, wherein the contact hole exposes the semiconductor substrate and the dummy contact hole is a hole formed by partially etching the interlayer insulating layer.

13. The semiconductor device according to claim 11, further comprising a metal interconnection line filled in the contact hole and the dummy contact hole.

14. The semiconductor device according to claim 11, wherein the metal interconnection line comprises at least selected from the group consisting of tungsten (W), aluminum (Al) and copper (Cu).

15. The semiconductor device according to claim 11, wherein an adjustable number of contact holes and dummy contact holes are formed to decrease a failure occurrence due to a difference in size of the contact holes and dummy contact holes formed on the active region and the dummy region, respectively of the semiconductor substrate.
